(19) United States
(12) Patent Application Publication
(10) Pub. No.: US 2015/0011074 A1
(43) Pub. Date: Jan. 8, 2015

(54) METHODS OF FABRICATING SEMICONDUCTOR DEVICES HAVING WRAPPING LAYER

(71) Applicant: SAMSUNG ELECTRONICS CO., LTD., Suwon-si (KR)

(72) Inventors: Dong-Hyun HAN, Gunpo-si (KR); Jin-Man CHANG, Suwon-si (KR)

(21) Appl. No.: 14/296,664

(22) Filed: Jun. 5, 2014

(30) Foreign Application Priority Data
Jul. 5, 2013 (KR) 10-2013-0079210

(51) Int. Cl. H01L 21/02; H01L 21/78; H01L 21/768

(52) U.S. Cl. CPC H01L 21/02109; H01L 21/76895; H01L 21/78
USPC 438/462; 438/627

(57) ABSTRACT

A method of fabricating a semiconductor device includes providing a substrate having first areas and second areas, forming first metal wires on the first areas of the substrate, forming second metal wires on the second areas of the substrate, forming an interlayer insulation layer to cover the first and second metal wires, forming pad patterns on the first metal wires, forming a passivation layer to cover the pad patterns on the interlayer insulation layer, and forming a wrapping layer on the passivation layer. The wrapping layer includes first openings that are vertically aligned with the pad patterns, and second openings that are disposed on the second areas and that horizontally connect the first openings with each other.

### CROSS-REFERENCE TO RELATED APPLICATION

Korean Patent Application No. 10-2013-0079210, filed on Jul. 5, 2013, in the Korean Intellectual Property Office, and entitled: “Methods Of Fabricating Semiconductor Devices Having Wrapping Layer,” is incorporated by reference herein in its entirety.

### BACKGROUND

Embodiments relate to semiconductor devices having wrapping layers and methods of fabricating the semiconductor devices.

### SUMMARY

Embodiments are directed to a method of fabricating a semiconductor device, including providing a substrate having first areas and second areas, forming first metal wires on the first areas of the substrate, forming second metal wires on the second areas of the substrate, forming an interlayer insulation layer to cover the first and second metal wires, forming pad patterns on the first metal wires, forming a passivation layer to cover the pad patterns on the interlayer insulation layer, and forming a wrapping layer on the passivation layer. The wrapping layer includes first openings that are vertically aligned with the pad patterns, and second openings that are disposed on the second areas and that horizontally connect the first openings with each other.

The wrapping layer may include a photo-sensitive polyimide.

The first openings may be vertically aligned with portions of the pad patterns and the first metal wires.

The second openings may include two straight lines parallel to each other.

Side edges of the first openings and the second openings on abutting the wrapping layer may be in a form of wavy lines.

The pad patterns may include aluminum.

The pad patterns may include a first barrier layer as a bottom layer, a core layer as a center layer center, and a second barrier layer as a top layer.

The first and second metal wires may include copper.

The second openings may be not vertically aligned with the second metal wires.

The wrapping layer may include an island-like wrapping pattern surrounded by the first and second openings.

The wrapping pattern may be vertically aligned with the second metal wires.

Embodiments are also directed to a method of fabricating a semiconductor device including preparing a wafer including a plurality of semiconductor chip areas and scribing lanes between the plurality of semiconductor chip areas, forming pad patterns and circuit patterns on the scribing lane of the wafer, forming a passivation layer to cover the pad patterns and the circuit patterns, forming a wrapping layer on the passivation layer, the wrapping layer including first openings to expose the passivation layer and second openings to expose the passivation layer and horizontally connect the first openings with each other, removing the passivation layer exposed through the first openings and exposing the pad patterns, and performing a sawing process or a laser drilling process along the scribing lanes and separating the semiconductor chip areas.

The first openings may be configured to be vertically aligned with center regions of the pad patterns. The second openings may be configured to be vertically aligned with an edge or a corner of the pad patterns.

The method may further include removing portions of the passivation layer that are exposed through the second openings to expose a surface of a substrate below the scribing lanes.

The circuit patterns may include a transistor and copper wires.

Embodiments are also directed to a method of fabricating a semiconductor device including preparing a wafer including a plurality of semiconductor chip areas and scribing lanes between the plurality of semiconductor chip areas. Preparing the scribing lanes includes forming first metal wires on first areas of a substrate in the scribing lanes between the plurality of semiconductor chip areas, forming second metal wires on second areas of the substrate in the scribing lanes between the plurality of semiconductor chip areas, forming an interlayer insulation layer to cover the first metal wires and the second metal wires, forming pad patterns on the interlayer insulation layer in the first areas, the pad patterns being electrically connected to the first metal wires through vias in the interlayer insulation layer, forming a passivation layer to cover the pad patterns and the interlayer insulation layer, forming a wrapping layer on the passivation layer, the wrapping layer including first openings to expose the passivation layer in the first areas and second openings to expose the passivation layer in the second areas, the second areas to horizontally connecting the first openings with each other.

The first openings may be vertically aligned with the pad patterns and the second openings may not be vertically aligned with the second metal wires.

The method may further include removing the passivation layer exposed through the first openings to expose the pad patterns.

The method may further include performing a sawing process or a laser drilling process along the scribing lanes and separating the semiconductor chip areas.

### BRIEF DESCRIPTION OF THE DRAWINGS

Features will become apparent to those of skill in the art by describing in detail exemplary embodiments with reference to the attached drawings in which:

FIG. 1A illustrates a top view of a wafer in accordance with embodiments, and FIG. 1B illustrates an enlarged layout pattern of region A shown in FIG. 1A;

FIG. 2A illustrates a layout pattern of a wrapping layer in region A of the wafer shown in FIG. 1B, FIG. 2B illustrates a layout pattern overlaying FIGS. 1B and 2A, and FIG. 2C illustrates a top view of region A;

FIG. 3A illustrates a layout pattern of the wrapping layer in region A of the wafer shown in FIG. 1B, FIG. 3B illustrates a layout pattern overlaying FIGS. 1B and 3A, and FIG. 3C illustrates a top view of region A;

FIG. 4A illustrates a layout pattern of the wrapping layer in region A of the wafer shown in FIG. 1B, FIG. 4B illustrates a layout pattern overlaying FIGS. 1B and 4A, and FIG. 4C illustrates a top view of region A;

FIG. 5A illustrates a layout pattern of region A of the wafer shown in FIG. 1A, FIG. 5B illustrates a layout pattern of the wrapping layer in region A of the wafer shown in FIG. 5A, FIG. 5C illustrates a layout pattern overlaying FIGS. 5A and 5B, and FIG. 5D illustrates a top view of region A;

FIGS. 6A to 6H illustrate stages of a method of fabricating semiconductor devices in accordance with embodiments.

FIGS. 7A to 7E illustrate stages of another method of fabricating semiconductor devices in accordance with embodiments;

FIG. 8A illustrates a schematic view of a memory module including at least one of semiconductor chips separated from wafers in accordance with embodiments;

FIG. 8B illustrates a schematic view of a memory card including at least one of semiconductor chips separated from wafers in accordance with embodiments;

FIGS. 8C and 8D illustrate schematic block views of electronic systems including at least one of semiconductor chips separated from wafers in accordance with embodiments; and

FIG. 8E illustrates a schematic view of a mobile wireless device including at least one of semiconductor chips separated from wafers in accordance with embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terminology used herein is for the purpose of describing particular embodiments only and is not intended to be limiting of the present inventive concept. As used herein, the singular forms “a,” “an,” and “the” are intended to include the plural forms as well, unless the context clearly indicates otherwise. As used herein, the term “and/or” includes any and all combinations of one or more of the associated listed items.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

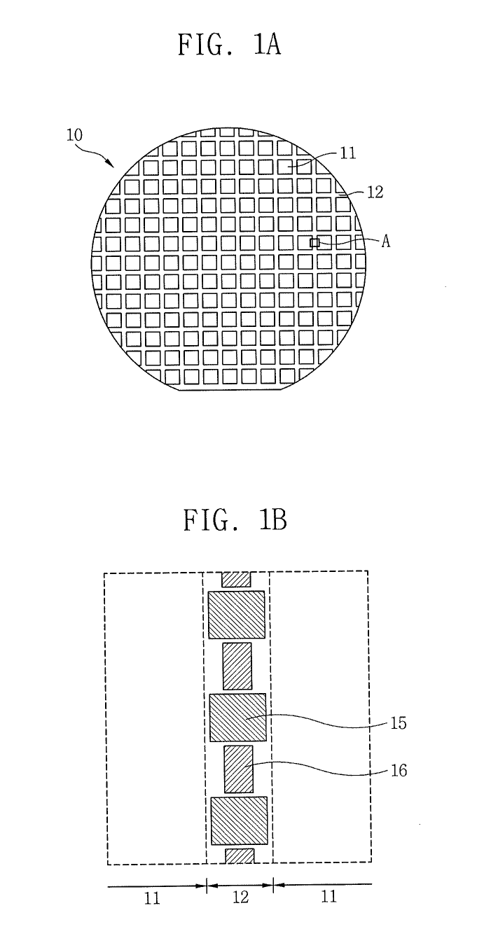

FIG. 1A illustrates a top view of a wafer 10 in accordance with embodiments. Referring to FIG. 1A, the wafer 10 may include a plurality of semiconductor chip areas 11 and a scribing lane 12. For example, FIG. 1A schematically illustrates the wafer 10 as it may exist before performing a dicing process such as sawing and laser drilling. The semiconductor chip areas 11 may include semiconductor devices that have been completed by individual fabrication processes. As an example, the semiconductor chip areas 11 are shown as tetragons. The scribing lane 12 may be disposed between the semiconductor chip areas 11. The term “scribing lane” refers to a space between semiconductor chip areas, such as, for example, where the dicing process is carried out. The semiconductor chip areas 11 may be isolated and separated from each other by the scribing lane 12.

FIG. 1B illustrates an enlarged layout pattern of region A of the wafer 10 shown in FIG. 1A in accordance with embodiments. Referring to FIG. 1B, the wafer 10 may include the scribing lane 12 between the semiconductor chip areas 11. The boundary between the semiconductor chip areas 11 and the scribing lane 12 is illustrated by dotted lines. The scribing lane 12 may include pad patterns 15 and circuit patterns 16. The pad patterns 15 and the circuit patterns 16 may be alternately arranged within the scribing lane 12.

The pad patterns 15 may include tetragonal metal plates. In some implementations, circuit patterns may also be formed under the pad patterns 15, but this feature will be omitted in the drawings for convenience of description.

The circuit patterns 16 may include various patterns or alignment key patterns for monitoring a process of fabricating semiconductor devices, or testing processing and/or electrical characteristics. The circuit patterns 16 may include copper wires. For instance, the circuit patterns 16 may be regions where copper wires are formed.

The pad patterns 15 may occupy wider regions than where the copper wires are arranged.

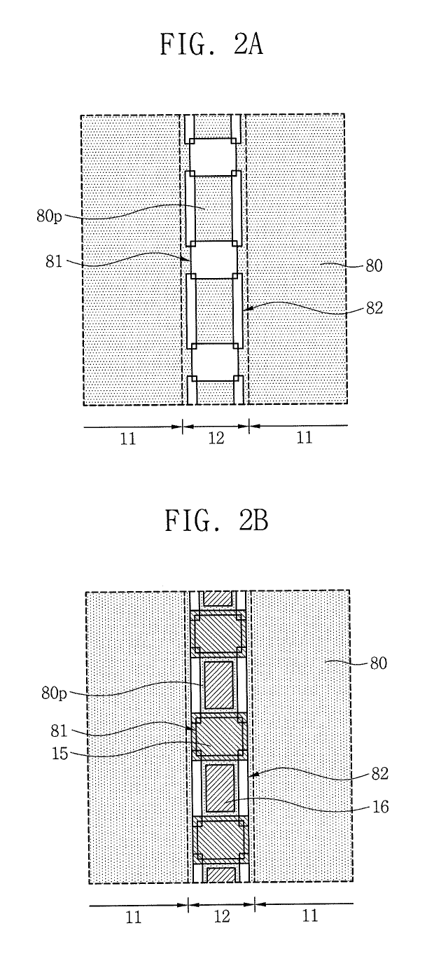

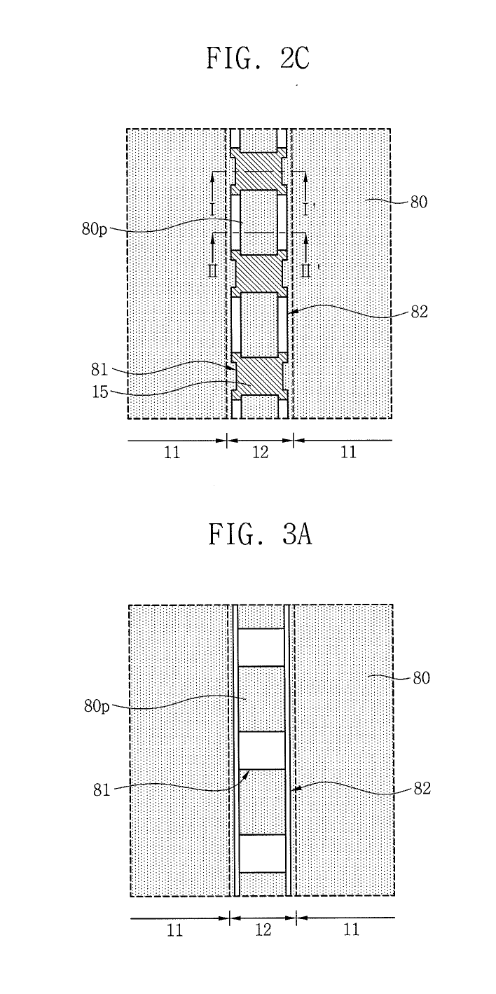

FIG. 2A illustrates a layout pattern of a wrapping layer 80 in region A of the wafer 10 shown in FIG. 1B in accordance with embodiments. Referring to FIG. 2A, the wrapping layer 80 may include window openings 81 and bridge openings 82. The wrapping layer 80 may contain a photo-sensitive polyimide.

The window openings 81 may be shaped similar to the pad patterns 15. For example, the window openings 81 may be formed in a shape of a tetragon.

The window openings 81 may be configured to be horizontally connected with each other by way of the bridge openings 82. The bridge openings 82 may be shaped as a multiplicity of bars. Each bridge opening 82 may connect respective corners of two adjacent window openings 81 with each other. A corner of each window opening 81 may be partly overlaid with an end or a corner of one of the bridge openings 82.

The wrapping layer 80 may include island-like wrapping patterns 80p, each island-like wrapping pattern 80p being confined by two window openings 81 and two bridge openings 82. The wrapping layers 80 covering two semiconductor chip areas 11 may be horizontally isolated from each other.

Side edges of the window openings 81 and the bridge openings 82 abutting on the wrapping layer 80 may be in a form of wavy lines.

FIG. 2B illustrates a layout pattern overlaying FIGS. 1B and 2A. Referring to FIG. 2B, the pad patterns 15 within the scribing lane 12 of the wafer 10 may be overlaid with the window openings 81. The window openings 81 may be overlay inner or central regions of the pad patterns 15. Corners of the pad patterns 15 may be overlaid with ends of the bridge openings 82. The circuit patterns 16 may not be overlaid with any of the window openings 81 or the bridge openings 82. The circuit patterns 16 the circuit patterns 16 may be overlaid with the wrapping patterns 80p and surrounded by the window openings 81 and the bridge openings 82.

FIG. 2C illustrates a top view of region A of the wafer 10 shown in FIG. 1B according to embodiments. Referring to FIG. 2C, while the top surface of the wafer 10 may be covered by the wrapping layer 80, the top central regions of the pad patterns 15 may be exposed through the window openings 81, and the corners of the pad patterns 15 may be partly exposed through the bridge openings 82. The outer edges of the pad patterns 15 may be covered by the wrapping layer 80, and not exposed through the window openings 81.

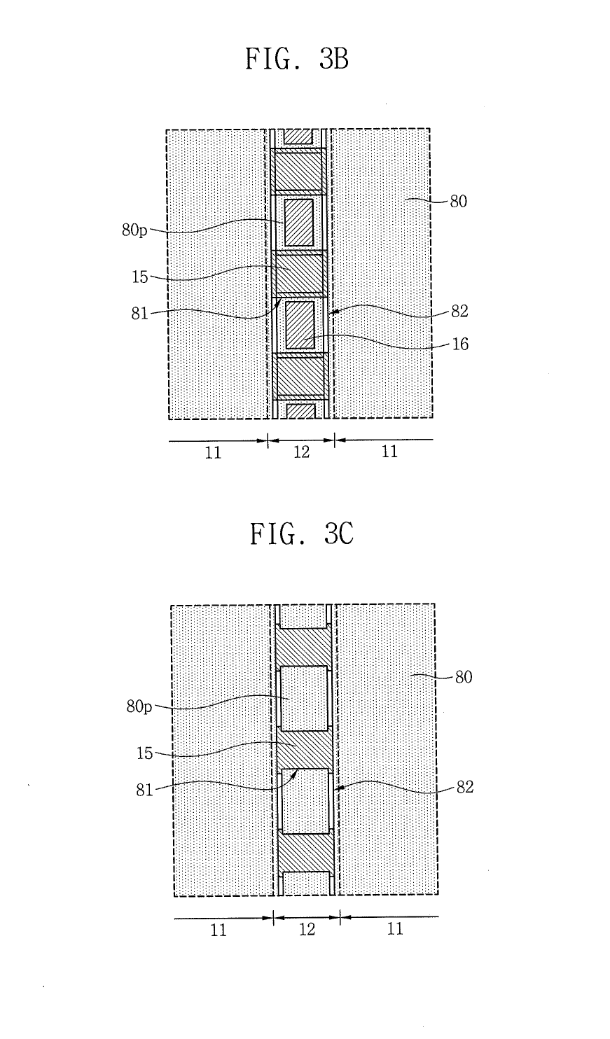

FIG. 3A illustrates a layout pattern of the wrapping layer 80 in region A of the wafer 10 shown in FIG. 1B in accordance with embodiments. Referring to FIG. 3A, the wrapping layer 80 may include the window openings 81 and the bridge openings 82. The bridge openings 82 may have two parallel linear or railed shapes each abutting on two side edges of the window openings 81. The window openings 81 may have patterns interconnected through the bridge openings 82 of parallel linear or railed shapes. The wrapping layer 80 may include the island-like wrapping patterns 80p confined by two window openings 81 and two bridge openings 82.

FIG. 3B illustrates a layout pattern overlaying FIGS. 1B and 3A. Referring to FIG. 3B, the pad patterns 15 within the scribing lane 12 of the wafer 10 according to embodiments may be overlaid with the window openings 81. The window openings 81 may overlay the inner or central regions of the pad patterns 15. The corners and/or two edges of the pad patterns 15 may be partly overlaid with the bridge openings 82.

FIG. 3C illustrates a top view of region A of the wafer 10 shown in FIG. 1B according to embodiments. Referring to FIG. 3C, while the top surface of the wafer 10 may be covered by the wrapping layer 80, the top face of the pad patterns 15 may be exposed through the window openings 81. The corners and/or the surface that is close to two edges of the pad patterns 15 may be partly exposed through the bridge openings 82.

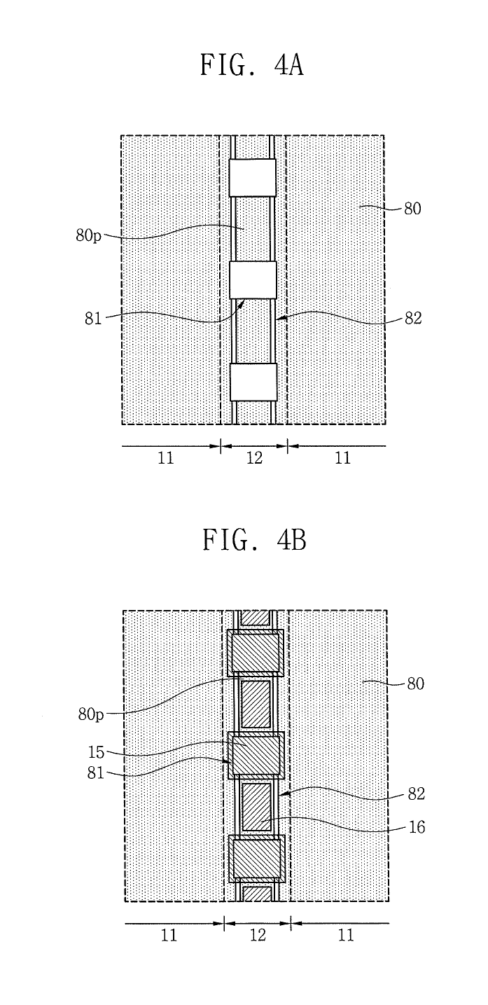

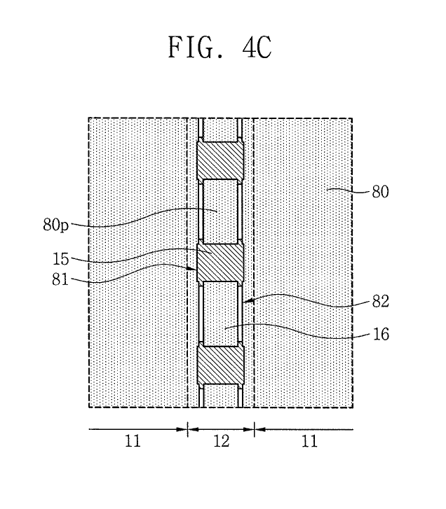

FIG. 4A illustrates a layout pattern of the wrapping layer 80 in region A of the wafer 10 shown in FIG. 1B in accordance with embodiments. Referring to FIG. 4A, the wrapping layer 80 may include the window openings 81 and the bridge openings 82. The bridge openings 82 may have their ends shaped as a multiplicity of bars abutting on their opposite edges of the window openings 81. The window openings 81 may have shapes horizontally interconnected with each other through the bar-like bridge openings 82. The wrapping layer 80 may include the island-like wrapping pattern 80p confined by two window openings 81 and two bridge openings 82.

Side edges of the window openings 81 and the bridge openings 82 abutting on the wrapping layer 80 may be in a form of wavy lines

FIG. 4B illustrates a layout pattern overlaying FIGS. 1B and 4A. Referring to FIG. 4B, the pad patterns 15 within the scribing lane 12 of the wafer 10 may be overlaid with the window openings 81. The window openings 81 may overlay the inner or central regions of the pad patterns 15. The corners and/or two edges of the pad patterns 15 may be partly overlaid with the bridge openings 82.

FIG. 4C illustrates a top view of region A of the wafer 10 shown in FIG. 1B according to embodiments. Referring to FIG. 4C, while the top surface of the wafer 10 may be covered by the wrapping layer 80, the top face of the pad patterns 15 may be exposed through the window openings 81, and two opposite edges of the pad patterns 15 may be partly exposed through the bridge openings 82. The circuit patterns 16 may not be exposed through the window openings 81 or the bridge openings 82. For example, the circuit patterns 16 may be fully covered by the wrapping pattern 80p.

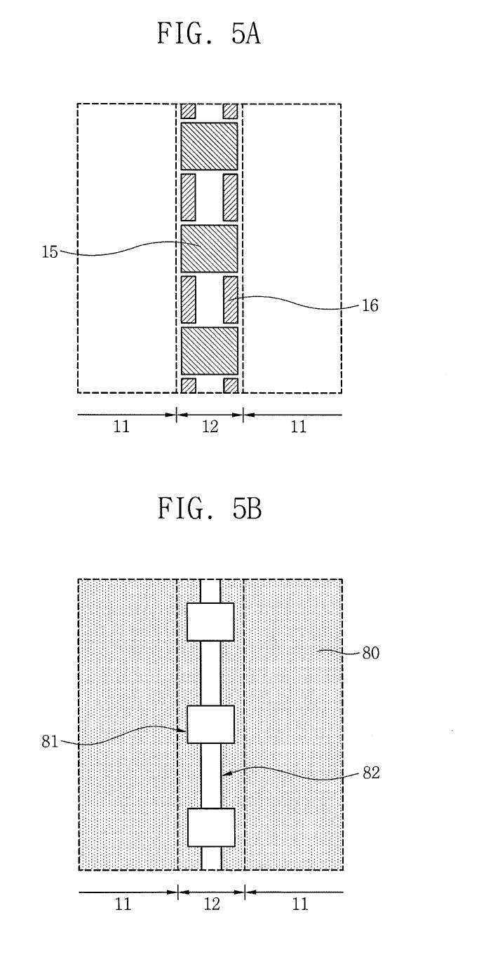

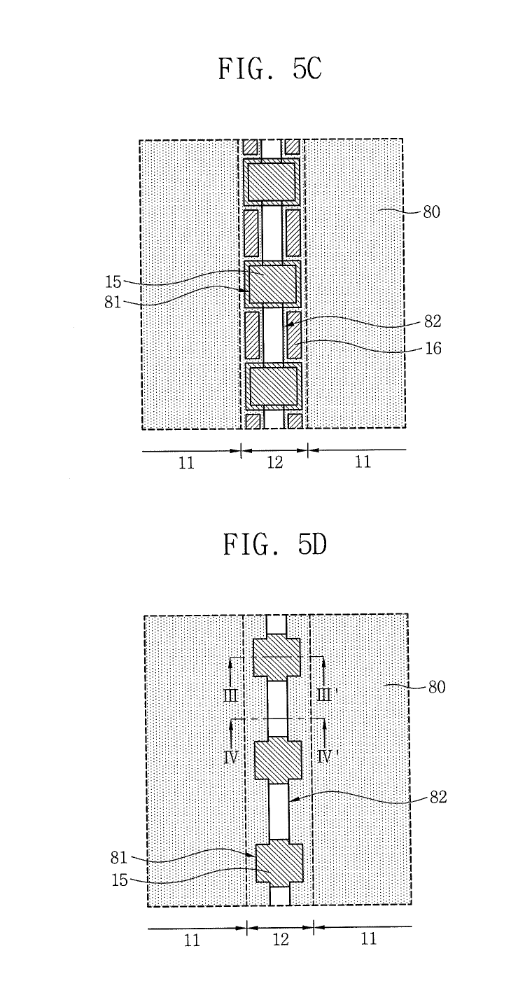

FIG. 5A illustrates a layout pattern of region A of the wafer 10 shown in FIG. 1A in accordance with embodiments. Referring to FIG. 5A, the wafer 10 may include the scribing lane 12 between the semiconductor chip areas 11. The scribing lane 12 may include the pad patterns 15 and the circuit patterns 16. At least two circuit patterns 16 may be disposed between two adjacent pad patterns 15. The circuit patterns 16 may be isolated from each other so as to be respectively close to the semiconductor chip areas 11.

FIG. 5B illustrates a layout pattern of the wrapping layer 80 in region A of the wafer 10 shown in FIG. 5A in accordance with embodiments. Referring to FIG. 5B, the wrapping layer 80 may include the window openings 81 and the bridge openings 82. The bridge openings 82 may be shaped as bars abutting on their opposite edges of the window openings 81 to separate the scribing lane 12. The window openings 81 may have shapes horizontally interconnected with each other through the bridge openings 82. The wrapping layer 80 covering the two semiconductor chip areas 11 may be separated from each other.

Side edges of the window openings 81 and the bridge openings 82 abutting on the wrapping layer 80 may be in a form of wavy lines

FIG. 5C illustrates a layout pattern overlaying FIGS. 5A and 5B. Referring to FIG. 5C, the pad patterns 15 within the scribing lane 12 of the wafer 10 according to embodiments may be overlaid with the window openings 81. The window openings 81 may be overlay the inner or central regions of the pad patterns 15. Two edges of the pad patterns 15 may be partly overlaid with the bridge openings 82. The circuit patterns 16 may not be overlaid with any of the window openings 81 and the bridge openings 82. The circuit patterns 16 may be covered with extensions of the wrapping layer 80 covering the semiconductor chip areas 11.

FIG. 5D illustrates a top view of region A of the wafer 10 shown in FIG. 5A in accordance with embodiments. Referring to FIG. 5D, while the top surface of the wafer 10 is covered by the wrapping layer 80, the top face of the pad patterns 15 may be exposed through the window openings 81. Two opposite edges of the pad patterns 15 may be partly exposed through the bridge openings 82. The circuit patterns 16 may not be exposed through the window openings 81 or the bridge openings 82.

Different embodiments described in conjunction with FIGS. 1A to 5D may be diversely combined with each other. For example, according to occupied areas and disposed positions of the circuit patterns 16, the wrapping layer 80 may include various combinations derivable from the layout patterns illustrated in FIGS. 2A, 3A, 4A, and 5A.

With the wafers 10 in this condition, a test process may be carried out. As an example, a test process may be performed without exposing copper wires to the atmosphere. If the copper wires are exposed to the atmosphere, they may be easily oxidized or may degenerate prior to the test process. If the copper wires lose their characteristics as conductors, the test process may not be performable under normal conditions. However, the wafers 10 according to embodiments are prevented or protected from exposure to the atmosphere, so that the subsequent test process may be performed under normal conditions.

The wafers 10 according to embodiments may include the window and bridge openings, 81 and 82, horizontally interconnected with each other. The wafer 10 according to embodiments may have the semiconductor chip areas 11 covered by the wrapping layer 80, which is horizontally divided. Additionally, the wafer 10 according to embodiments may have the circuit patterns 16 covered by the island-like wrapping patterns 80p. Therefore, when the semiconductor chip areas 11 are separated by sawing, laser drilling, or dicing, the wrapping layer 80 may remain entirely on the semiconductor chip areas 11 without damage. Accordingly, the semiconductor chip areas 11 may be stably isolated and protected, physically, chemically, and electrically, from external circumstances.

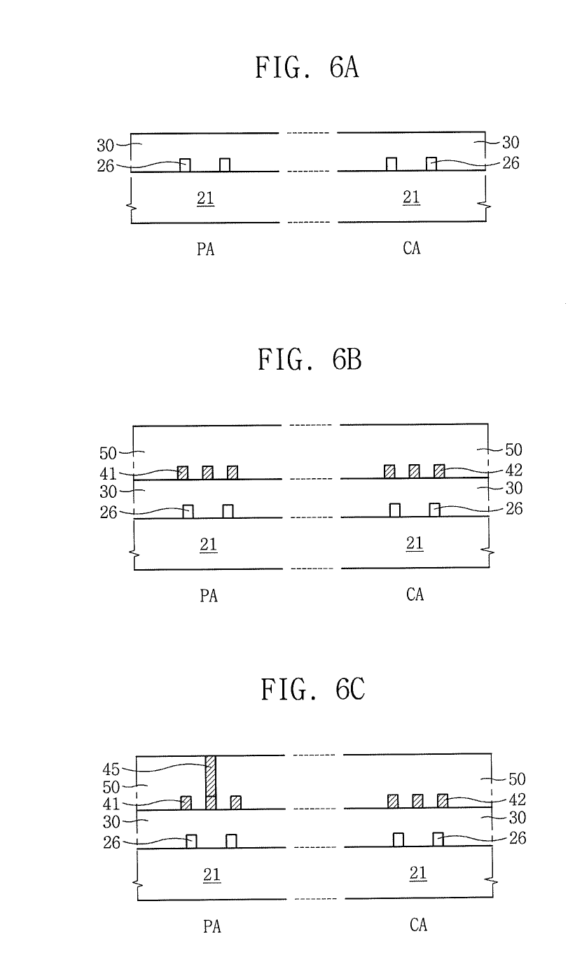

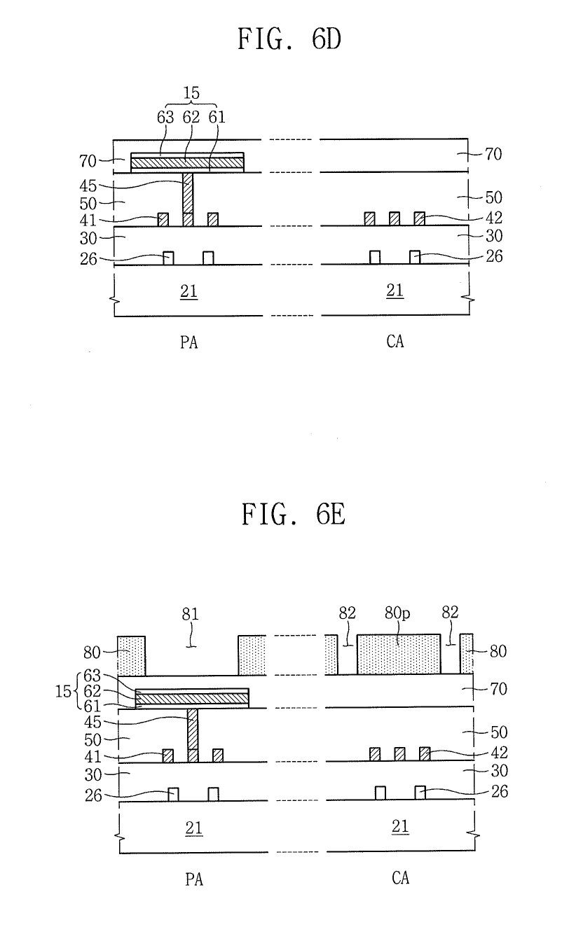

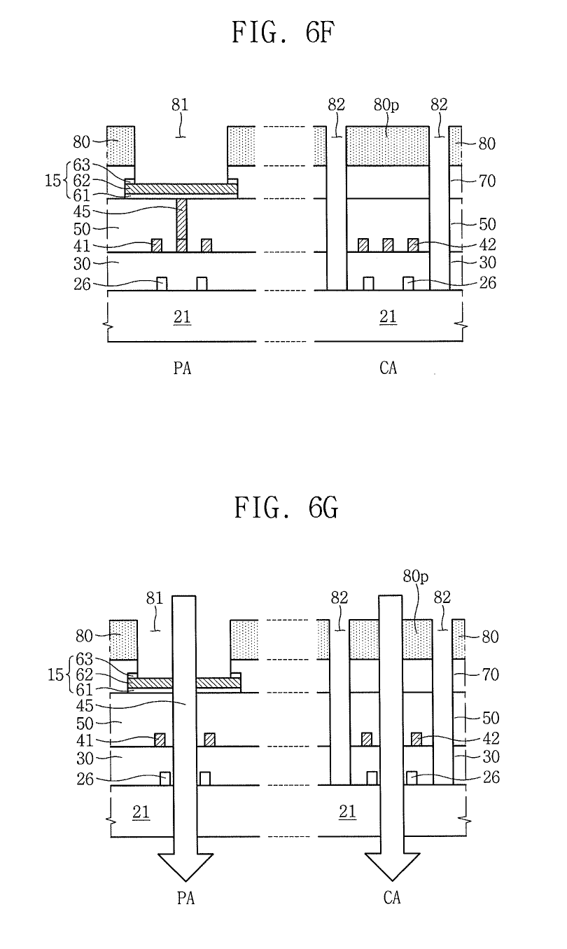

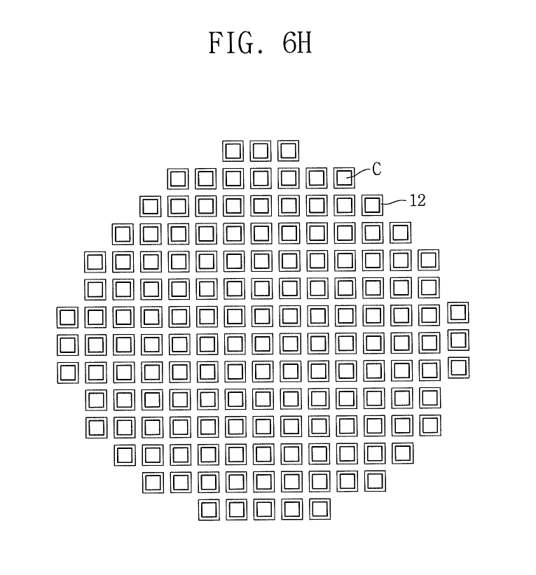

FIGS. 6A to 6H illustrate stages of a method of fabricating semiconductor chips in accordance with embodiments. Throughout FIGS. 6A to 6H, the sections are taken along lines I-I′ (a pad pattern area) and II-II′ (a circuit pattern area) of FIG. 2C. Referring to FIG. 6A, a method of fabricating semiconductor chips in accordance with embodiments may include forming a transistor 26 and a lower interlayer insulation layer 30 on a substrate 21 including a pad pattern area PA and a circuit pattern area CA. The substrate 21 may include a wafer. The transistor 26 may include a metal oxide semiconductor field effect transistor (MOSFET). The transistor 26 is schematically represented by its gate electrode simply shown in the drawings. The lower interlayer insulation layer 30 may contain silicon oxide.

Referring to FIG. 6B, the method may include forming a pad metal wire 41 and a circuit metal wire 42 on the lower interlayer insulation layer 30, and forming an upper interlayer insulation layer 50 to cover the pad metal wire 41 and the circuit metal wire 42. The pad metal wire 41 and the circuit metal wire 42 may contain copper. The upper interlayer insulation layer 50 may contain silicon oxide.

Referring to FIG. 6C, the method may include forming a via plug 45 passing through the upper interlayer insulation layer 50 and electrically connecting to the pad metal wire 41. The via plug 45 may be formed on/in the pad pattern area PA. The via plug 45 may contain a metal such as copper (Cu), aluminum (Al), or tungsten (W).

Referring to FIG. 6D, the method may include forming the pad pattern 15, which is connected to the via plug 45, and forming a passivation layer 70 on the upper interlayer insulation layer 50. The pad pattern 15 may be formed on/in the pad pattern area PA. The pad pattern 15 may include a lower barrier layer 61, a core layer 62, and an upper barrier layer 63. The lower barrier layer 61 and the upper barrier layer 63 may contain titanium (Ti), titanium nitride (TiN), tantalum (Ta), tantalum nitride (TaN), or other kinds of barrier metals. The core layer 62 may contain aluminum (Al), tungsten (W), nickel (Ni), copper (Cu), or other kinds of metals. The passivation layer 70 may contain silicon nitride, silicon oxide, or polyimide.

Referring to FIG. 6E, the method may include forming the wrapping layer 80, which includes the window opening 81 and the bridge opening 82, on the passivation layer 70. The window opening 81 may be formed in the pad pattern area PA and the bridge opening 82 may be formed in the circuit pattern area CA. The window opening 81 and the bridge opening 82 may expose the passivation layer 70. The wrapping layer 80 may include the wrapping pattern 80p between two bridge openings 82. The wrapping pattern 80p may vertically overlay the circuit metal wire 42 of the circuit pattern area CA.

Referring to FIG. 6F, the method may include removing the passivation layer 70 exposed through the window opening 81 and the bridge opening 82. In the pad pattern area PA, the passivation layer 70 exposed through the window opening 81 may be removed to expose the pad pattern 15. For example, the upper barrier layer 63 of the pad pattern 15 may be partly removed to expose the core layer 62. In the circuit pattern area CA, portions of the passivation layer 70, the upper interlayer insulation layer 50, and the lower interlayer insulation layer 30 that are exposed through the bridge openings 82 may be removed. The portions of the upper interlayer insulation layer 50 and the lower interlayer insulation layer 30 exposed through the bridge openings 82 may be removed partly or entirely. For example, the substrate 21 may be exposed. The pad metal wire 41 may be located vertically under the window opening 81. On the other hand, the circuit metal wire 42 may not be located vertically under the bridge opening 82. With the wafer 10 in this structural condition, a test process may be performed. As an example, it may be possible to conduct a process for testing the electrical characteristics of fabricated semiconductor devices by inputting/outputting electrical signals through the pad pattern 15. The pad metal wire 41 and/or the circuit metal wire 42, including copper wires, may not be exposed to the atmosphere. Therefore, the copper wires can be protected in the test process against negative effects arising from oxidation or degeneration.

Referring to FIG. 6G, the method may include separating the substrate 21 by sawing or laser drilling. After the test process, exposure of the copper wires disposed in the scribing lane 12 to the atmosphere may be of no concern, since the copper wires will not be further used.

FIG. 6H illustrates unit semiconductor chips C separated by way of the aforementioned method. The scribing lane 12 may be arranged around the outside of the separated unit semiconductor chips C.

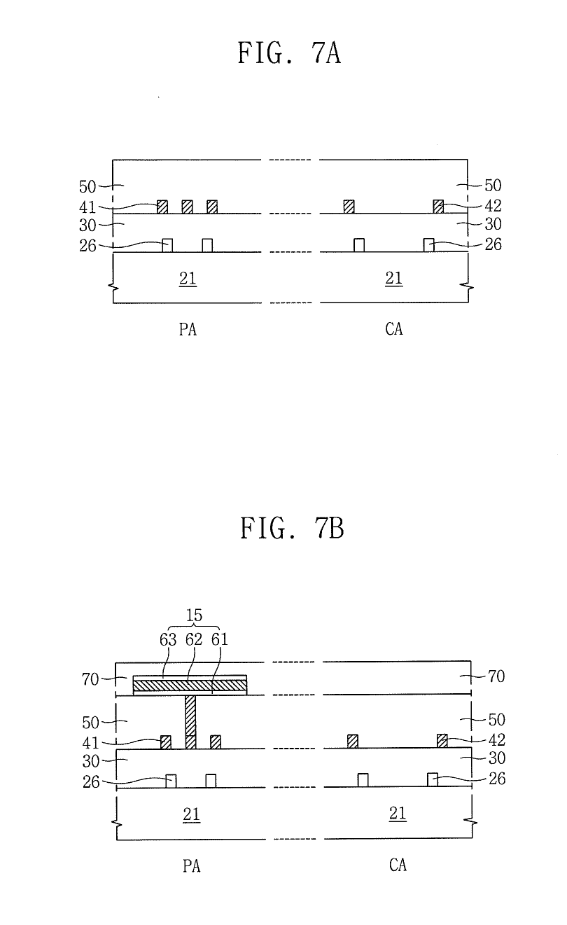

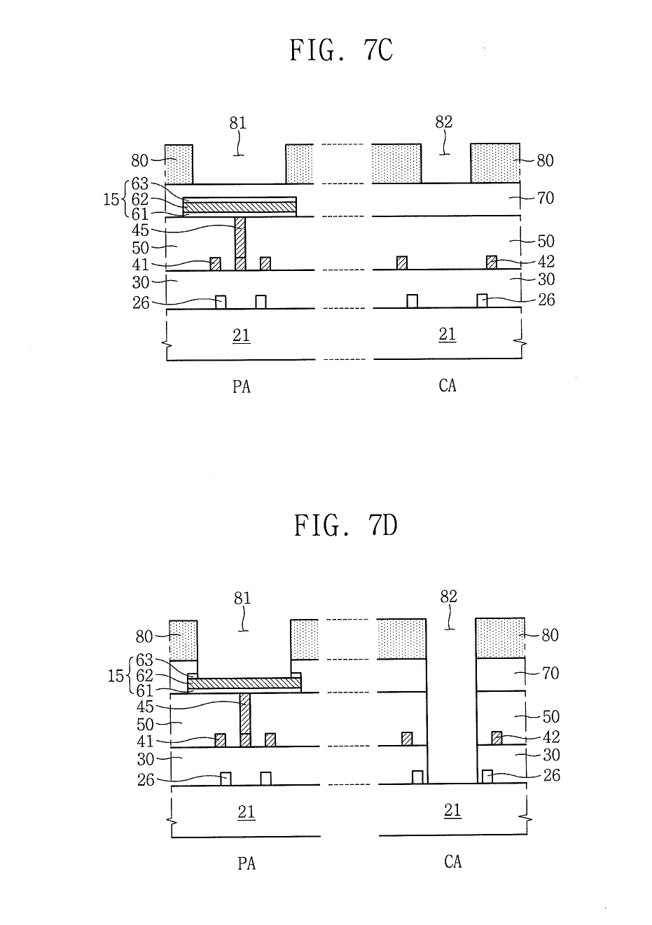

FIGS. 7A to 7E illustrate stages of a method of fabricating semiconductor chips in accordance with embodiments. Exemplarily, throughout FIGS. 7A to 7E, sections are taken along lines III-III′ (a pad pattern area) and IV-IV′ (a circuit pattern area) of FIG. 5D. Referring to FIG. 7A, a method of fabricating semiconductor chips in accordance with embodiments may include forming a transistor 26, a lower interlayer insulation layer 30, pad metal wires 41, circuit metal wires 42, and an upper interlayer insulation layer 50, which covers the pad metal wires 41 and the circuit metal wires 42, on the substrate 21 including the pad pattern area PA and the circuit pattern area CA. The circuit metal wire 42 may not be formed on/in the central region of the circuit pattern area CA. The circuit metal wire 42 may contain copper.

Referring to FIG. 7B, the method may include forming a via plug 45 passing through the upper interlayer insulation layer 50 and electrically connected to the pad metal wire 41, and forming a pad pattern 15, which is connected to the via plug 45, and a passivation layer 70 on the upper interlayer insulation layer 50.

Referring to FIG. 7C, the method may include forming a wrapping layer 80, which has the window opening 81 and the bridge opening 82, on the passivation layer 70. The window opening 81 may be formed in the pad pattern area PA, and the bridge opening 82 may be formed in the circuit pattern area CA. The bridge openings 82 may be arranged on the central region of the circuit pattern area CA. The bridge openings 82 may not be vertically aligned with the circuit metal wires 42.

Referring to FIG. 7D, the method may include removing the passivation layer 70 exposed through the window opening 81 and the bridge opening 82. In this structural condition, a test process may be performed. As an example, it may be possible to conduct a process for testing the electrical characteristics of semiconductor devices fabricated by inputting/outputting electrical signals through the pad pattern 15. The pad metal wire 41 and/or the circuit metal wire 42, including copper wires, may not be exposed to the atmosphere. Therefore, the copper wires can be protected in the test process against negative effects arising from oxidation or degeneration.

Referring to FIG. 7E, the method may include separating the substrate 21 by sawing or laser drilling. The bridge opening 82 may have a width wider than the separated breadth. Afterward, referring to FIG. 6H, the unit semiconductor chips C may be separated and then completed in fabrication.

In the methods of fabricating semiconductor devices in accordance with embodiments, the window and bridge openings, 81 and 82, of the wrapping layer 80 are controlled so as to not expose the pad metal wire 41 and the circuit metal wire 42. Accordingly, a test process may be carried out under normal conditions while fabricating the semiconductor devices.

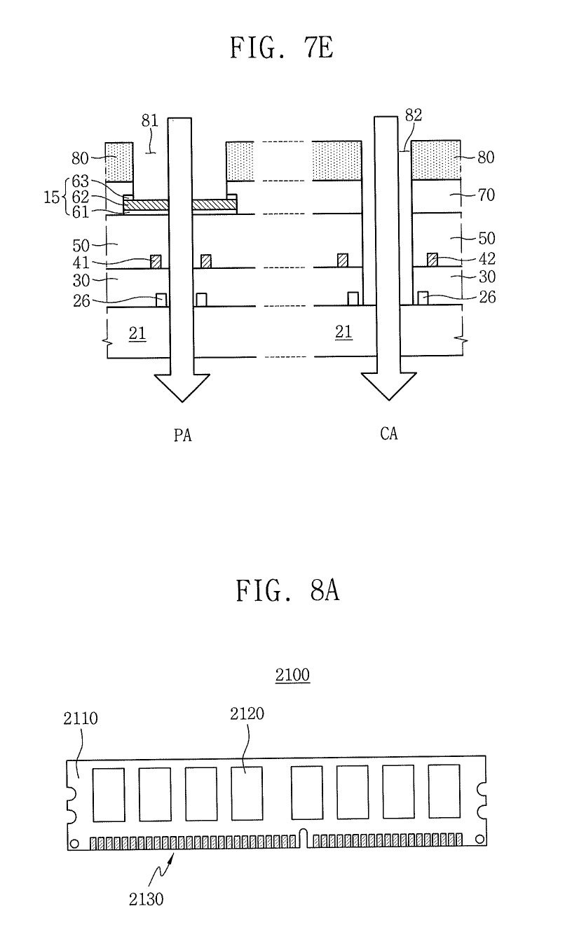

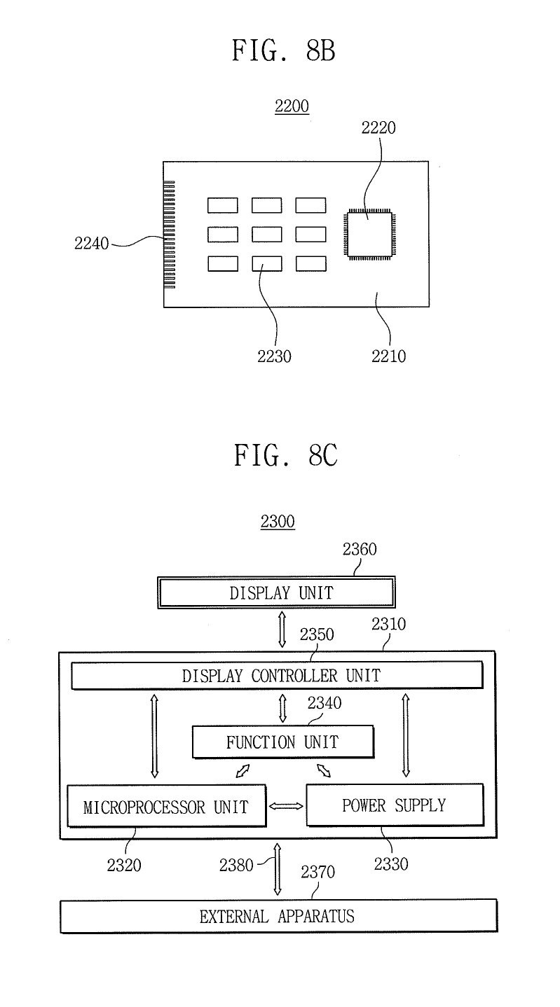

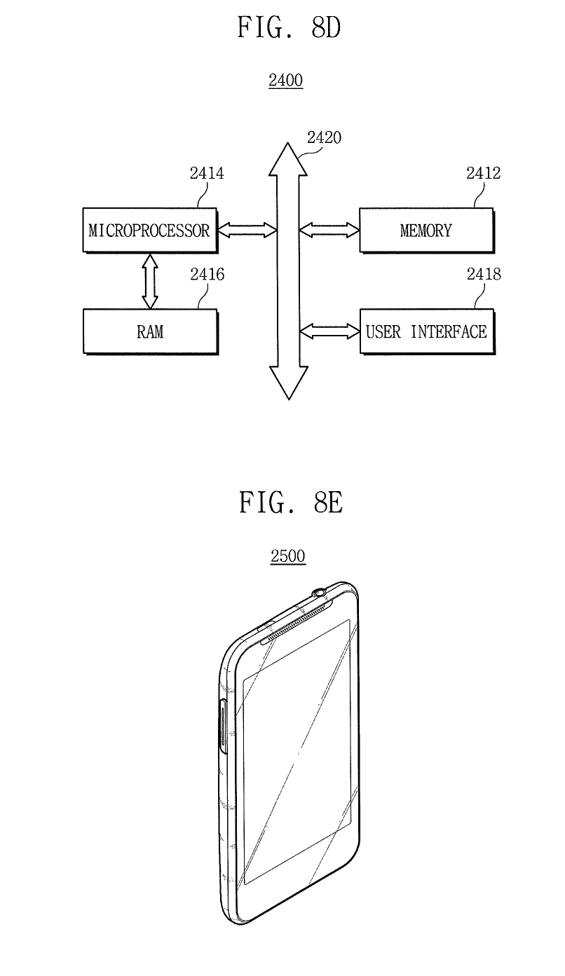

FIG. 8A illustrates a schematic view of a memory module 2100 including at least one of the semiconductor chips C separated from the wafers 10 in accordance with embodiments. Referring to FIG. 8A, the memory module 2100 may include a memory module substrate 2110, a plurality of memory devices 2120 disposed on the memory module substrate 2110, and a plurality of terminals 2130. The memory module substrate 2110 may include a printed circuit board (PCB) or a wafer. The memory devices 2120 may include a semiconductor package accommodating the semiconductor chips C that are separated from the wafers 10 according to embodiments. The plurality of terminals 2130 may include a conductive metal. Each terminal may be electrically connected with each memory device 2120.

FIG. 8B illustrates a schematic view of a memory card 2200 including at least one of the semiconductor chips C separated from the wafers 10 in accordance with embodiments. Referring to FIG. 8B, the memory card 2200 may include the semiconductor chips C (referred to in FIG. 8B by reference character 2230), mounted on a memory card substrate 2210, separated from the wafers 10 according to embodiments. The memory card 2200 may further include a microprocessor 2220 mounted on the memory card substrate 2210. Input/output terminals 2240 may be disposed at at least one of edges of the memory card substrate 2210.

FIG. 8C illustrates a schematic block view of an electronic system 2300 including at least one of the semiconductor chips C separated from the wafers 10 in accordance with embodiments. Referring to FIG. 8C, the electronic system 2300 may include at least one of the semiconductor chips C separated from the wafers 10. The system 2300 may include a body 2310. The body 2310 may include a microprocessor unit 2320, a power supply 2330, a function unit 2340, and/or a display controller unit 2350. The body 2310 may be made up of a system board or mother board having a PCB. The microprocessor unit 2320, the power supply 2330, the function unit 2340, and the display controller unit 2350 may be mounted or installed on the body 2310. A display unit 2360 may be disposed on the top face or in the outside of the body 2310. For example, the display unit 2360 may be disposed on the surface of the body 2310 to display an image that is processed by the display controller unit 2350. The power supply 2330 may be supplied with a voltage from an external power source, may divide the voltage into different voltage levels, and then may supply the divided voltages into the microprocessor unit 2320, the function unit 2340, and the display controller unit 2350. The microprocessor unit 2320 may be supplied with a voltage from the power supply 2330 and may control the function unit 2340 and the display unit 2360. The function unit 2340 may perform various functions for the electronic system 2300. For example, in the case where the electronic system 2300 is a mobile electronic product such as a mobile phone, the function unit 2340 may include a variety of components capable of executing wireless communication functions such as video output to the display unit 2360, or audio output to a speaker by way of dialing or exchanging messages with an external apparatus 2370. If the electronic system 2300 includes a camera, the function unit 2340 may act as an image processor. In another implementation, if the electronic system 2300 is coupled with a memory card in order to extend its storage capacity, the function unit 2340 may act as a memory card controller. The function unit 2340 may exchange signals with the external apparatus 2370 by way of a wired or wireless communication unit 2380. Additionally, if the electronic system 2300 uses a universal serial bus (USB) for extending its functionality, the function unit 2340 may act as an interface controller. At least one of the semiconductor chips C separated from the wafers 10 described in the foregoing embodiments may be included in at least one of the microprocessor unit 2320 and the function unit 2340.

FIG. 8D illustrates a schematic block view of another electronic system 2400 including at least one of the semiconductor chips C separated from the wafers 10 in accordance with embodiments. Referring to FIG. 8D, the electronic system 2400 may include at least one of the semiconductor chips C separated from the wafers 10. The electronic system 2400 may be employed in fabricating a mobile device or a computer. For example, the electronic system 2400 may include a memory system 2412, a microprocessor 2414 performing data communication through a bus 2420, a random access memory (RAM) 2416, and a user interface 2418. The microprocessor 2414 may program and control the electronic system 2400. The RAM 2416 may be used as an operation memory of the microprocessor 2414. For instance, the microprocessor 2414 or the RAM 2416 may include at least one of the semiconductor chips C separated from the wafers 10 according to embodiments. The microprocessor 2414, the RAM 2416, and/or other components may be assembled in a single package. The user interface 2418 may be used for inputting data into the electronic system 2400 or outputting data from the electronic system 2400. The memory system 2412 may store operation codes for the microprocessor 2414, data processed by the microprocessor 2414, or external input data. The memory system 2412 may include a controller and a memory device.

FIG. 8E illustrates a schematic view of a mobile wireless device 2500 including at least one of the semiconductor chips C separated from the wafers 10 in accordance with embodiments. The mobile wireless device 2500 may be a tablet personal computer (tablet PC), for example. At least one of the semiconductor chips C separated from the wafers 10 may be employed, as well as in a tablet PC, in a portable computer such as a notebook, an MPEG-1 audio layer 3 (MP3) player, an MP4 player, a navigation device, a solid state disk (SSD), a table computer, an automobile, or home electric appliances.

By way of summation and review, to enhance the productivity of semiconductor devices, scribing lanes in a wafer of the semiconductor devices have gradually been made narrower. As the scribing lanes have become narrower, a more precise process such as laser drilling has become desirable to separate the devices from the wafer.

Embodiments provide a wafer and semiconductor devices having a wrapping layer. Embodiments provide a wafer and semiconductor devices where openings of a wrapping layer are horizontally interconnected with each other. Embodiments provide a wafer and semiconductor devices where copper wires and openings of a wrapping layer are not vertically aligned. Embodiments provide a method of fabricating semiconductor devices having a wrapping layer. Embodiments provide a method of fabricating semiconductor devices where openings of a wrapping layer are horizontally interconnected with each other. Embodiments provide a method of fabricating semiconductor devices where copper wires and openings of a wrapping layer are not vertically aligned.

As can be seen from the foregoing, in the wafers and the semiconductor devices according to various embodiments, copper wires may be arranged so as to not be exposed to the atmosphere. If the copper wires were to be exposed to the atmosphere, they could be easily oxidized or could degenerate before conducting a test process. The copper wires may not maintain their characteristics as conductors after being exposed to the atmosphere. Accordingly, the test process may not be carried out under normal conditions. However, in the wafers and the semiconductor devices according to embodiments, copper wires are arranged so as to not be exposed to the atmosphere, enabling a subsequent test process to be performed under normal conditions.

The wafers and the semiconductor devices according to various embodiments may include window openings and bridge openings interconnected to each other horizontally. The wafers and the semiconductor devices according to various embodiments may include the semiconductor chip areas covered by the wrapping layer, which is horizontally divided. The wafers and the semiconductor devices according to various embodiments may include the circuit patterns covered by wrapping patterns shaped as islands. Accordingly, when separating the semiconductor chip areas using sawing, laser drilling, or dicing, the wrapping layer on the semiconductor chip areas may be entirely retained without damage. Therefore, the semiconductor chip areas may be stably isolated and, physically, chemically, and electrically protected from the external circumstances.

The window openings and the bridge openings may be arranged so as to not expose the pad metal wires and the circuit metal wires. Accordingly, it may be possible to normally perform a test process normally while fabricating the semiconductor devices.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A method of fabricating a semiconductor device, the method comprising:
providing a substrate having first areas and second areas;
forming first metal wires on the first areas of the substrate;
forming second metal wires on the second areas of the substrate;
forming an interlayer insulation layer to cover the first and second metal wires;
forming pad patterns on the first metal wires;
forming a passivation layer to cover the pad patterns on the interlayer insulation layer; and
forming a wrapping layer on the passivation layer,
wherein the wrapping layer includes:
first openings that are vertically aligned with the pad patterns; and
second openings that are disposed on the second areas and that horizontally connect the first openings with each other.

2. The method as claimed in claim 1, wherein the wrapping layer includes a photo-sensitive polyimide.

3. The method as claimed in claim 1, wherein the first openings are vertically aligned with portions of the pad patterns and the first metal wires.

4. The method as claimed in claim 1, wherein the second openings include two straight lines parallel to each other.

5. The method as claimed in claim 1, wherein side edges of the first openings and the second openings abutting on the wrapping layer are in a form of wavy lines.

6. The method as claimed in claim 1, wherein the pad patterns include aluminum.

7. The method as claimed in claim 6, wherein the pad patterns include a first barrier layer as a bottom layer; a core layer as a center layer center; and a second barrier layer as a top layer.

8. The method as claimed in claim 1, wherein the first and second metal wires include copper.

9. The method as claimed in claim 1, wherein the second openings are not vertically aligned with the second metal wires.

10. The method as claimed in claim 1, wherein the wrapping layer includes an island-like wrapping pattern surrounded by the first and second openings.

11. The method as claimed in claim 10, wherein the wrapping pattern is vertically aligned with the second metal wires.

12. A method of fabricating a semiconductor device, the method comprising:
preparing a wafer including a plurality of semiconductor chip areas and scribing lanes between the plurality of semiconductor chip areas;
forming pad patterns and circuit patterns on the scribing lane of the wafer;
forming a passivation layer to cover the pad patterns and the circuit patterns;
forming a wrapping layer on the passivation layer, the wrapping layer including first openings to expose the passivation layer and second openings to expose the passivation layer and horizontally connect the first openings with each other;
removing the passivation layer exposed through the first openings and exposing the pad patterns; and
performing a sawing process or a laser drilling process along the scribing lanes and separating the semiconductor chip areas.

13. The method as claimed in claim 12, wherein the first openings are configured to be vertically aligned with center regions of the pad patterns, and
the second openings are configured to be vertically aligned with an edge or a corner of the pad patterns.

14. The method as claimed in claim 12, further comprising removing portions of the passivation layer that are exposed through the second openings to expose a surface of the substrate below the scribing lanes.

15. The method as claimed in claim 12, wherein the circuit patterns include a transistor and copper wires.

16. A method of fabricating a semiconductor device, the method comprising:
preparing a wafer including a plurality of semiconductor chip areas and scribing lanes between the plurality of semiconductor chip areas, wherein preparing the scribing lanes includes:
forming first metal wires on first areas of a substrate in the scribing lanes between the plurality of semiconductor chip areas;
forming second metal wires on second areas of the substrate in the scribing lanes between the plurality of semiconductor chip areas;
forming an interlayer insulation layer to cover the first metal wires and the second metal wires;
forming pad patterns on the interlayer insulation layer in the first areas, the pad patterns being electrically connected to the first metal wires through vias in the interlayer insulation layer;
forming a passivation layer to cover the pad patterns and the interlayer insulation layer;
forming a wrapping layer on the passivation layer, the wrapping layer including first openings to expose the passivation layer in the first areas and second openings to expose the passivation layer in the second areas, the second areas to horizontally connecting the first openings with each other.

17. The method as claimed in claim 16, wherein the first openings are vertically aligned with the pad patterns and the second openings are not vertically aligned with the second metal wires.

18. The method as claimed in claim 17, further including removing the passivation layer exposed through the first openings to expose the pad patterns.

19. The method as claimed in claim 18, further including performing a sawing process or a laser drilling process along the scribing lanes and separating the semiconductor chip areas.
